(19) United States
(12) Patent Application Publication
(10) Pub. No.: US 2014/0131540 A1
(43) Pub. Date: May 15, 2014

(54) BASE ASSEMBLY

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventor: BAO-QUAN SHI, Shenzhen (CN)

(73) Assignees: HON HAI PRECISION INDUSTRY CO., LTD, New Taipei (TW); HONG FU JIN PRECISION INDUSTRY (ShenZhen) CO., LTD., Shenzhen (CN)

(21) Appl. No.: 13/953,659

(22) Filed: Jul. 29, 2013

(30) Foreign Application Priority Data
Nov. 14, 2012 (CN) 2012104562795

(51) Int. Cl. H05K 7/02

(52) U.S. Cl. CPC H05K 7/02
USPC 248/346.03

(57) ABSTRACT

A base assembly includes a base, a panel body, and a securing member. The base includes a base body and a mounting portion extending from the base body. The mounting portion defines a pivot hole. The panel body defines an opening corresponding to the pivot hole. The securing member includes a head portion, a pivot shaft extending from the head portion, and a securing portion secured to the pivot shaft. The pivot shaft is pivotably mounted in the pivot hole. The base is located between the head portion and the securing portion. The securing portion is located in the opening and is configured to rotate to engage the panel body.

### BACKGROUND

1. Technical Field

The present disclosure generally relates to an assembly for a base.

2. Description of Related Art

A CPU is a main chip in a computer. The CPU is installed on a base. However, a base is mounted on a printed circuit board via glue or screws, which makes mounting the base laborious and time-consuming.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of one embodiment of a base assembly, the base assembly including a plurality of securing members.

FIG. 2 is an exploded, isometric view of one embodiment of a securing member of FIG. 1.

FIG. 3 is an assembled view of the base assembly of FIG. 1.

FIG. 4 is another assembled view of the base assembly of FIG. 1.

FIG. 5 is a view of the base of FIG. 3, the base being secured.

FIG. 6 is another view of the base of FIG. 4, the base being secured.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

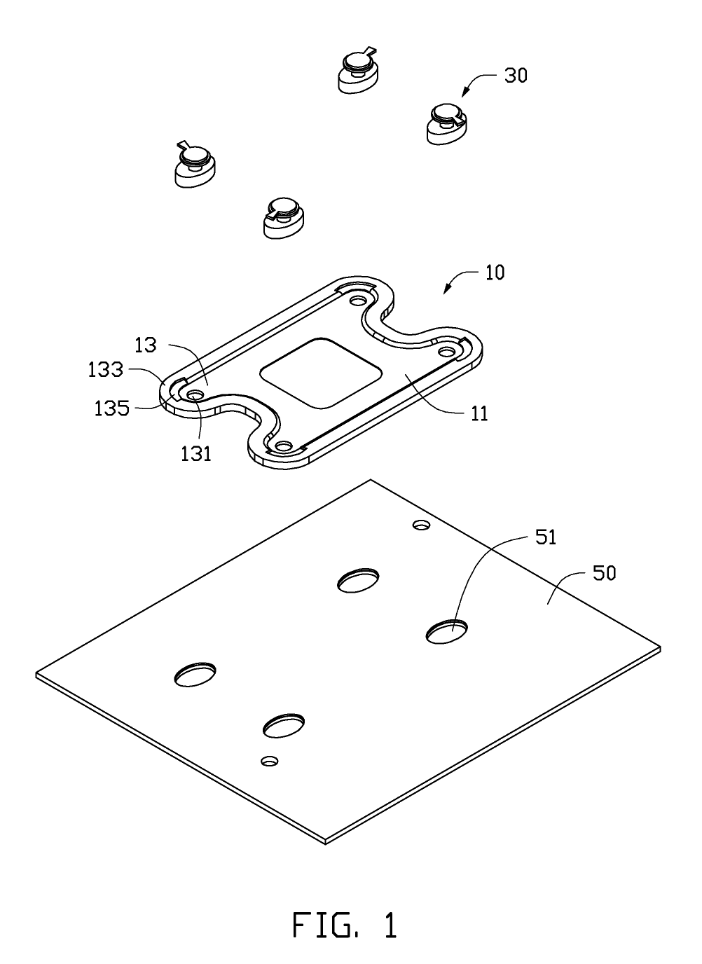

FIG. 1 shows that a base assembly, according to one embodiment, includes a base 10, four securing members 30, and a panel body 50. In one embodiment, the base 10 is used for mounting a CPU (not shown). The panel body 50 is a printed circuit board.

The base 10 includes a base body 11 and four mounting portions 13 extending from the base body 11. Each mounting portion 13 defines a pivot hole 131. Each mounting portion 13 includes a flange 133. The flange 133 defines a recess portion 135. The recess portion 135 is arc-shaped and runs 90 degrees around the pivot hole 131.

The panel body 50 defines four openings 51 corresponding to the four pivot holes 131. The openings 51 are ellipse-shaped.

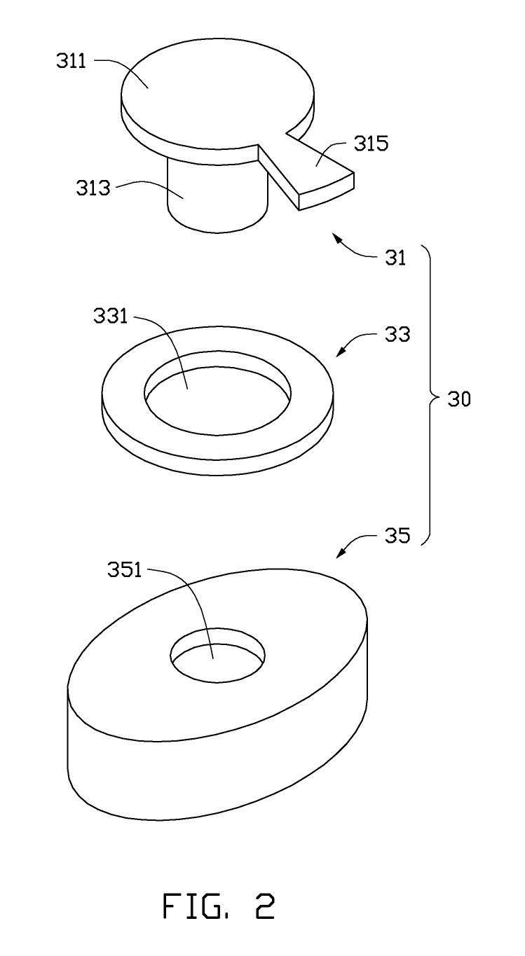

FIG. 2 shows that each securing member 30 includes a pivot portion 31, a gasket 33, and a securing portion 35. The pivot portion 31 includes a head portion 311, a pivot shaft 313 extending from the head portion 311, and a pivot arm 315 extending from the head portion 311. The pivot arm 315 is substantially perpendicular to the pivot shaft 313. The cross section of the head portion 311 is greater than that of the pivot shaft 313 taken along a plane and the pivot hole 131. The cross section of the pivot shaft 313 is less than the pivot hole 131. The gasket 33 defines a through hole 331. The securing portion 35 is ellipse-shaped and defines a securing hole 351.

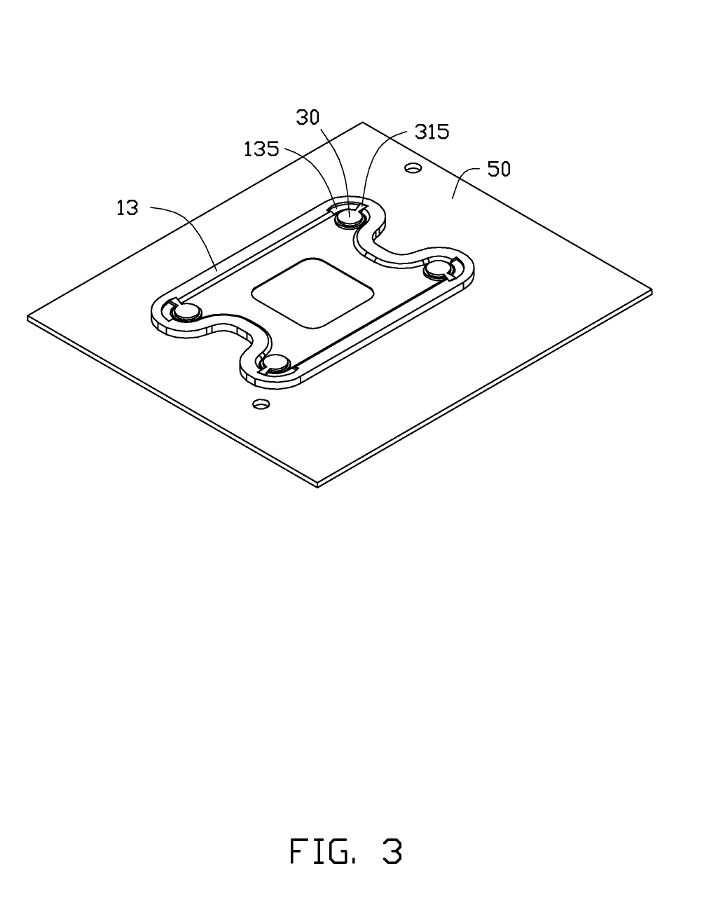

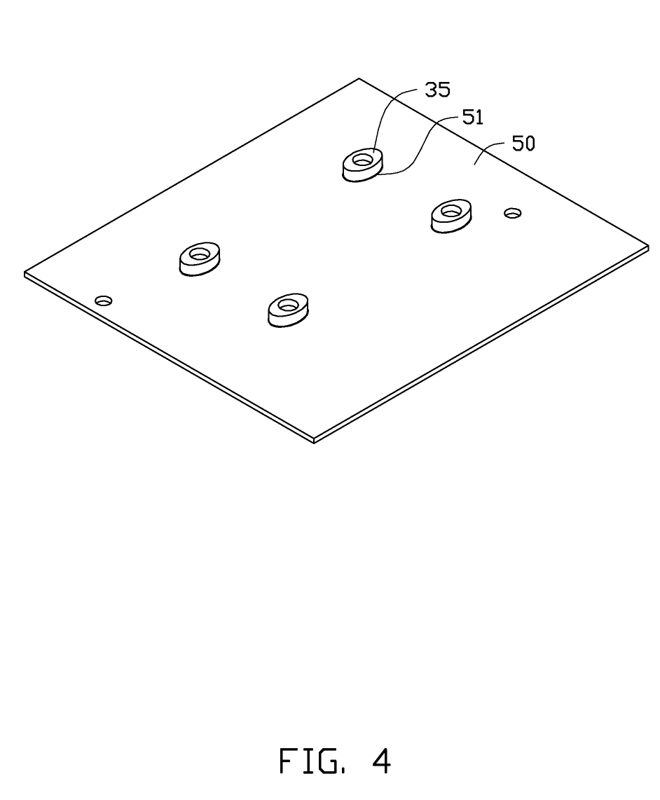

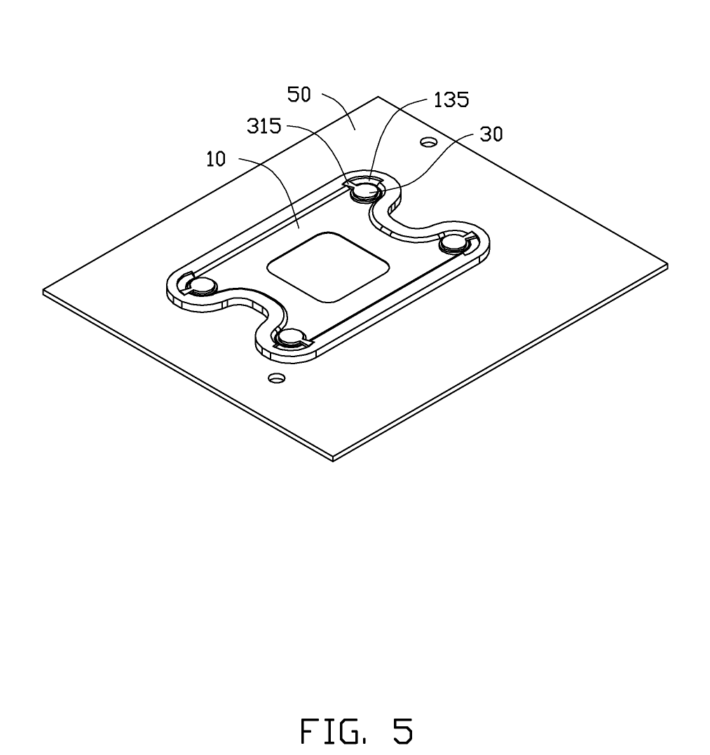

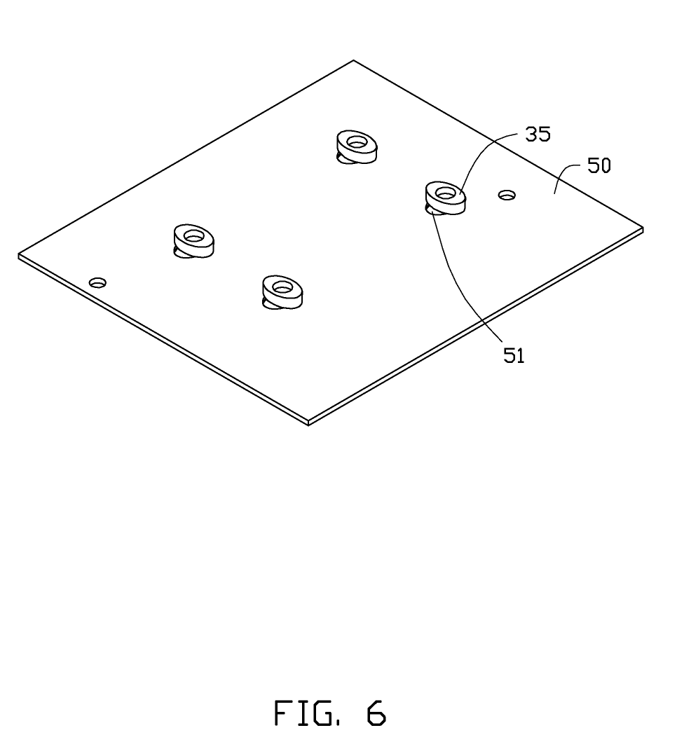

FIGS. 3 to 6 show that in assembly, the pivot shaft 313 of each securing member 30 passes through the through hole 331 of the gasket 33 and the pivot hole 131 of the base 10. Then, the pivot shaft 313 of each securing member 30 is inserted into the securing hole 351 of the corresponding securing portion 35, thereby pivotably mounting the securing members 30 to the base 10. At this time, the pivot arm 315 of each securing member 30 is located in the corresponding recess portion 135. The base 10 is placed on a first surface of the panel body 50 to enable the securing portion 35 of each securing member 30 to align with and be received by the corresponding openings 51 of the panel body 50. The pivot arms 315 are rotated to rotate the securing portions 35, such that the securing portions 35 resist the edges of the openings 51, thereby securing the base 10 on the panel body 50. In one embodiment, the rotation angle of the pivot arm 315 is 90 degrees.

In disassembly, the pivot arms 315 are rotated to drive the securing portions 35 to rotate to enable the securing portions 35 to disengage from the edges of the openings 51, thereby dismounting the base 10 from the panel body 50.

It is to be understood, however, that even though numerous characteristics and advantages of the embodiments have been set forth in the foregoing description, together with details of the structure and function of the embodiments, the disclosure is illustrative only, and changes may be made in detail, especially in the matters of shape, size, and arrangement of parts within the principles of the present disclosure to the full extent indicated by the broad general meaning of the terms in which the appended claims are expressed.

What is claimed is:

1. A base assembly comprising:
a base, the base comprises a base body and a mounting portion extending from the base body; the mounting portion defines a pivot hole;
a panel body, the panel body defines an opening corresponding to the pivot hole; and
a securing member, the securing member comprises a head portion, a pivot shaft extending from the head portion, and a securing portion secured to the pivot shaft; the pivot shaft is pivotably mounted in the pivot hole; the base is located between the head portion and the securing portion; and the securing portion is located in the opening and is configured to rotate to engage the panel body.

2. The base assembly of claim 1, wherein the securing member further comprises a pivot arm extending from the head portion, and the pivot arm is configured to be operated to drive the securing portion to rotate.

3. The base assembly of claim 2, wherein the mounting portion comprises a flange; the flange defines a recess portion; and the pivot arm is placed in the recess portion.

4. The base assembly of claim 3, wherein the recess portion is arc-shaped, and the pivot arm is configured to slide in the recess portion when the securing member rotates.

5. The base assembly of claim 4, wherein an angle, corresponding to a radian of the recess portion, is 90 degree.

6. The base assembly of claim 1, wherein a cross section of the securing portion is ellipse-shaped taken along a plane substantially parallel to the panel body, and the opening is ellipse-shaped.

7. The base assembly of claim 1, wherein the securing member further comprises a gasket; the gasket defines a through hole; the pivot shaft is located in the through hole; and the gasket is located between the head portion and the mounting portion.

8. A base assembly comprising:
a base, the base comprises a base body and a mounting portion extending from the base body;
a panel body, the panel body defines an opening; and
a securing member pivotably mounted to the base, the securing member comprises a securing portion; the securing portion is configured to pass through the opening to be in a first position and rotate from the first position to a second position to engage an edge of the opening, thereby enabling the panel body to be placed between the securing portion and the base.

9. The base assembly of claim 8, wherein the mounting portion defines a pivot hole; the securing member further comprises a head portion and a pivot shaft extending from the head portion; the securing portion is secured to the pivot shaft; the pivot shaft is pivotably mounted in the pivot hole; and the base is located between the head portion and the securing portion.

10. The base assembly of claim 9, wherein the securing member further comprises a pivot arm extending from the head portion, and the pivot arm is configured to be operated to drive the securing portion to rotate.

11. The base assembly of claim 10, wherein the mounting portion comprises a flange; the flange defines a recess portion; and the pivot arm is placed in the recess portion.

12. The base assembly of claim 11, wherein the recess portion is arc-shaped, and the pivot arm is configured to slide in the recess portion when the securing member rotates.

13. The base assembly of claim 12, wherein an angle, corresponding to a radian of the recess portion, is 90 degree.

14. The base assembly of claim 9, wherein the securing member further comprises a gasket; the gasket defines a through hole; the pivot shaft is located in the through hole; and the gasket is located between the head portion and the mounting portion.

15. The base assembly of claim 8, wherein a cross section of the securing portion is ellipse-shaped taken along a plane substantially parallel to the panel body, and the opening is ellipse-shaped.
